(19) United States
(12) Patent Application Publication
(10) Pub. No.: US 2013/0248925 A1
(43) Pub. Date: Sep. 26, 2013

(54) POWER SEMICONDUCTOR DEVICE

(71) Applicant: KABUSHIKI KAISHA TOSHIBA, Tokyo (JP)

(72) Inventor: Ryohei GEJO, Kanagawa-ken (JP)

(73) Assignee: KABUSHIKI KAISHA TOSHIBA, Tokyo (JP)

(21) Appl. No.: 13/781,622

(22) Filed: Feb. 28, 2013

(30) Foreign Application Priority Data
Mar. 26, 2012 (JP) 2012-068629

(51) Int. Cl. H01L 29/739

(52) U.S. Cl. CPC H01L 29/7397
USPC 257/139

(57) ABSTRACT

According to an embodiment, a power semiconductor device includes a semiconductor substrate, a base layer, a device portion, a guard ring, and an insulator. The semiconductor substrate includes a drift layer with a first conductive type. The base layer has a second conductive type and is selectively formed in a surface of the drift layer. The device portion is formed on the surfaces of the base layer and the drift layer. The guard ring has a second conductive type and is disposed in plural and is selectively formed in the surface of the drift layer around the device portion. The insulator is buried in at least one of the guard rings.

### CROSS REFERENCE TO RELATED APPLICATION

This application is based upon and claims the benefit of priority from the prior Japanese Patent Application No. 2012-068629, filed on Mar. 26, 2012, the entire contents of which are incorporated herein by reference.

### FIELD

Embodiments described herein relate to a power semiconductor device.

### BACKGROUND

Recently, an insulated gate bipolar transistor (IGBT) has been widely used as a power semiconductor device having a high breakdown voltage and being able to control large current. The IGBT is used as a switching device and therefore requires a breakdown voltage according to uses. In order to obtain a predetermined breakdown voltage, when a termination portion has a guard ring structure, there is a problem in that a termination length may increase when termination efficiency increases. Further, in order to obtain higher breakdown voltage, there has been known a semiconductor device by forming trench gates, which extend into the semiconductor device so as to face each other, between electrodes that are disposed on upper and lower surfaces of the termination portion, to prevent the trench gates from extending to a counter electrode of a depletion layer. However, there is a problem in that the semiconductor device in which the trench gate structure is disposed in the termination portion has a complicated structure and is not easily manufactured.

### BRIEF DESCRIPTION OF THE DRAWINGS

FIG. 1 is a plan view of an IGBT according to a first embodiment;

FIG. 2 is a partial cross-sectional view taken along dashed dotted line A-A′ of FIG. 1;

FIGS. 3A and 3B are partial cross-sectional views illustrating a simulation structure at a termination portion of an IGBT device;

FIG. 4 is a voltage-current characteristic diagram illustrating current ICE (A) of the IGBT device illustrated in FIGS. 3A and 3B;

FIGS. 5A, 5B, and 5C are equipotential maps inside the IGBT device illustrated in FIGS. 3A and 3B;

FIGS. 6A and 6B are current distribution diagrams inside the IGBT device illustrated in FIGS. 3A and 3B;

FIGS. 7A and 7B are graphs illustrating a change of a breakdown voltage of the IGBT device when an interval L between a bottom surface of a trench and a bottom surface of a guard ring is changed;

FIG. 8 is a partial cross-sectional view illustrating a schematic configuration of an IGBT device according to a second embodiment; and

FIG. 9 is a partial cross-sectional view illustrating a schematic configuration of an IGBT device according to a third embodiment.

### DETAILED DESCRIPTION

According to an embodiment, a power semiconductor device includes a semiconductor substrate, a base layer, a device portion, a guard ring, and an insulator. The semiconductor substrate includes a drift layer with a first conductive type. The base layer has a second conductive type and is selectively formed in a surface of the drift layer. The device portion is formed on the surfaces of the base layer and the drift layer. The guard ring has a second conductive type and is disposed in plural and is selectively formed in the surface of the drift layer around the device portion. The insulator is buried in at least one of the guard rings.

Hereinafter, a plurality of further embodiments will be described with reference to the drawings. In the drawings, the same reference numerals designate the same or similar portions.

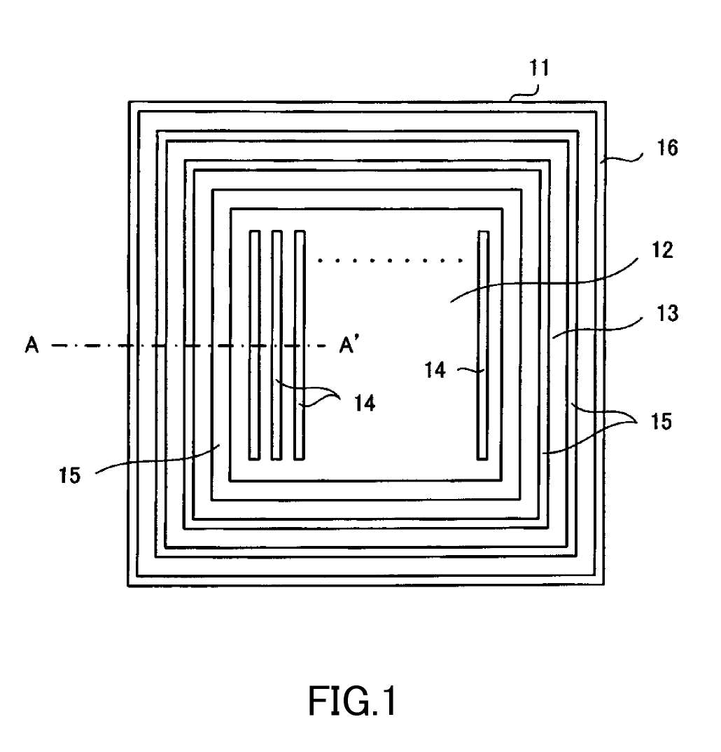

A power semiconductor device according to a first embodiment will be described with reference to the accompanying drawings. FIG. 1 is a plan view schematically illustrating a substrate surface pattern from which an emitter electrode and other electrodes of an insulated gate bipolar transistor (IGBT) that is a power switching device are removed.

As illustrated in FIG. 1, an IGBT 11 includes a device portion 12 with a rectangular shape at a central portion of a semiconductor substrate with a substantially rectangular shape. A termination portion 13 is disposed around the device portion 12. A plurality of elongated trench gates 14 is disposed in parallel inside the device portion 12. The termination portion 13 includes a plurality of guard rings 15 around the device portion 12. An equivalent potential ring (EQPR) layer 16 with a ring shape is disposed at an outermost circumferential portion of the termination portion 13.

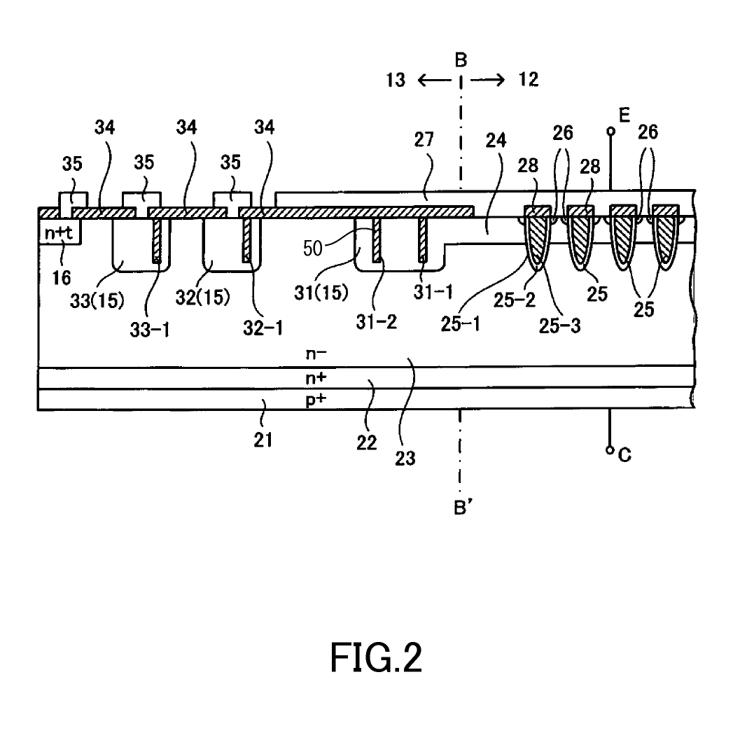

FIG. 2 is a partial cross-sectional view taken along dashed dotted line A-A′ of FIG. 1. As illustrated in FIG. 2, a right portion of dashed dotted line B-B′ of FIG. 2. corresponds to the device portion 12. The semiconductor substrate includes a p+ type collector layer 21, an n+ type buffer layer 22, and an n− type drift layer 23. The p+ type collector layer 21, the n+ type buffer layer 22, and the n− type drift layer 23 are sequentially formed and stacked. The semiconductor substrate has the n− type drift layer 23 at a surface side. A p type base layer 24 is selectively formed in a surface of the n− type drift layer 23. A plurality of trench gates 25 penetrating through the p type base layer 24 from the surface of the p type base layer 24 in a depth direction of the substrate and arriving inside the n− type drift layer 23 is disposed in the p type base layer 24. The device portions 12 are selectively formed on the surfaces of the p type base layer 24 and the n− type drift layer 23. The p+ type collector layer 21 has a higher impurity concentration than that of the p type base layer 24. The n+ type buffer layer 22 has a higher impurity concentration than that of the n− type drift layer 23.

The trench gate 25 includes a gate electrode 25-3 made of a polysilicon film, and the like. The gate electrode 25-3 is formed in a trench 25-1 formed in the p type base layer 24 via a gate insulating film 25-2 with a thin film. An n type emitter layer 26 is selectively formed in the surface of the p type base layer 24 at both sides of the trench gate 25. An emitter electrode 27 connected with the n type emitter layer 26 is disposed at the surface of the p type base layer 24. An insulating film 28 is respectively provided at a top portion of the trench gates 25 so as to insulate the trench gates 25 and the emitter electrode 27. The emitter electrode 27 is connected to an emitter electrode terminal E, the p+ type collector layer 21 that is a lowermost layer of the substrate is connected to a collector electrode terminal C. The gate electrodes 25-3 of each trench gate 25 are connected to each other and are connected to a gate electrode terminal G (not illustrated).

A left portion of dashed dotted line B-B′ of FIG. 2 corresponds to the termination portion 13 a. The termination portion 13 includes a guard ring 31, a guard ring 32, and a guard ring 33. The guard ring 31 is connected to the p type base layer 24 of the device portion 12 and is a p type innermost circumferential guard ring formed around the device portion 12 with a ring shape. The guard ring 32 is a p type outer circumferential guard ring formed at the outside of the guard ring 31 with a ring shape. The guard ring 33 is a p type outermost circumferential guard ring formed at the outermost circumferential side of the guard ring 32 in a ring shape. The guard ring 31, the guard ring 32, and the guard ring 33 each include at least one of trench 31-1, trench 31-2, trench 32-1, and trench 33-1 formed by using reactive ion etching (RIE), for example. The trenches 31-1, 31-2 formed in the guard ring 31 are disposed in the vicinity of both ends of the guard ring 31. The trench 32-1 formed in the guard ring 32 is disposed in the vicinity of the inner circumferential end of the guard ring 32. The trench 33-1 formed in the guard ring 33 is disposed in the vicinity of the inner circumferential end of the guard ring 33.

An insulator 50 made of a silicon oxide film formed by thermal oxidation and chemical vapor deposition (CVD) is buried in the trench 31-1, the trench 31-2, the trench 32-1, and the trench 33-1. Here, the silicon oxide film is used as the insulator 50, but an undoped polycrystalline silicon film, an undoped amorphous silicon film, an insulating organic film (polyimide film, for example), and the like, may be used instead. In this case, a silicon thermally-oxidized film formed by thermally oxidizing the silicon substrate may be formed on a side and a bottom portion of the trench. The surface of the n− type base layer 23 on which the guard ring 31, the guard ring 32, and the guard ring 33 are formed is covered with an insulating film 34. The insulating film 34 divides between the emitter electrode 27 and the guard ring 31 in the vicinity of the guard ring 31. The insulating film 34 is partially removed in upper portions of the guard ring 32, the guard ring 33, and the EQPR layer 16, and thus upper portions of the guard ring 32, the guard ring 33, and the EQPR layer 16 is exposed. E ach field plate electrode 35 is disposed on the exposed portions. The field plate electrode 35 is a floating electrode, for example, in which potential is not set. The guard ring 31 is connected to the emitter electrode 27 via the p type base layer 24 in a portion in which the insulating film 34 is not formed.

As described above, the guard ring 31, the guard ring 32, and the guard ring 33 each include the trench 31-1, the trench 31-2, the trench 32-1, and the trench 33-1, the insulator 50 is respectively buried in the trench 31-1, the trench 31-2, the trench 32-1, and the trench 33-1. For this reason, in the IGBT 11 of the embodiment, when a reverse bias is applied between the collector and the emitter, it is possible to increase an electric field around a bottom portion of the trench, and to disperse a field concentration point. Therefore, it is possible to improve a breakdown voltage of a device.

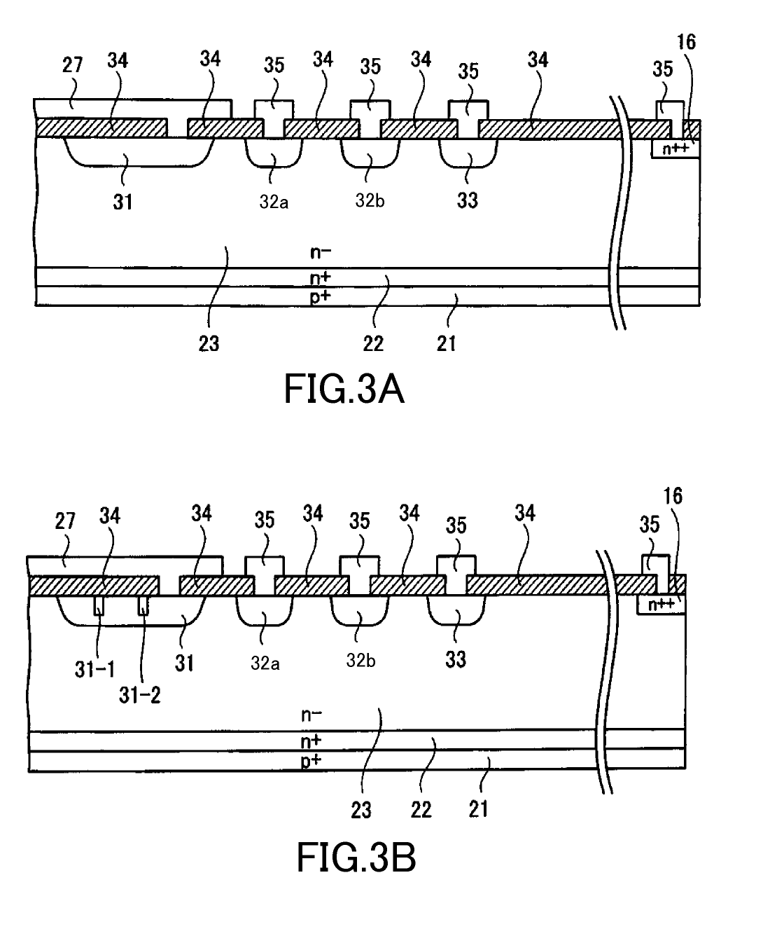

In the embodiment, the improvement of the breakdown voltage of the device is calculated by simulation, and thus the effect is confirmed. Hereinafter, the details thereof will be described with reference to FIGS. 3 to 6.

FIG. 3 is a partial cross-sectional view illustrating a simulation structure at a termination portion of an IGBT device. FIG. 3A illustrates a conventional structure and FIG. 3B illustrates a structure of the embodiment. In FIGS. 3A and 3B, portions corresponding to the structure of the device termination portion illustrated in FIG. 2 are denoted by the corresponding reference numerals and the detained description of the portions will be omitted.

As illustrated in FIGS. 3A and 3B, in the simulation structure of the circumferential end of the IGBT device, the p+ type collector layer 21, the n+ type buffer layer 22, and the n− type drift layer 23 are sequentially formed and stacked. In the surface of the n− type drift layer 23, the guard ring 31, a guard ring 32a, a guard ring 32b, and the guard ring 33 is disposed around the device portion 12. The guard ring 31 is the p type innermost circumferential guard ring with a ring shape. The guard ring 32a and the guard ring 32b are a p type outer circumferential guard ring with a ring shape at the outside of the guard ring 31. The guard ring 33 is the outermost circumferential guard ring with a ring shape at the outermost circumferential sides of the guard ring 32a and the guard ring 32b. However, both the simulation structures of the circumferential ends of the IGBT devices illustrated in FIGS. 3A and 3B have the reversed left portion and right portion with respect to the structure of the IGBT device illustrated in FIG. 2. In FIGS. 3A and 3B, the right portion is the termination portion and the left portion is the device portion (not illustrated).

In the simulation structure at the circumferential end of the IGBT device illustrated in FIG. 3A, none of the guard ring 31, the guard ring 32a, the guard ring 32b, and the guard ring 33 include the trench 31-1, the trench 31-2, the trench 32-1 and the trench 33-1 illustrated in FIG. 2.

In the simulation structure at the circumferential end of the IGBT device illustrated in FIG. 3B, the trench 31-1 and the trench 31-2 buried the insulator in the guard ring 31 are formed. The guard ring 32a, the guard ring 32b, and the guard ring 33 do not include the trench.

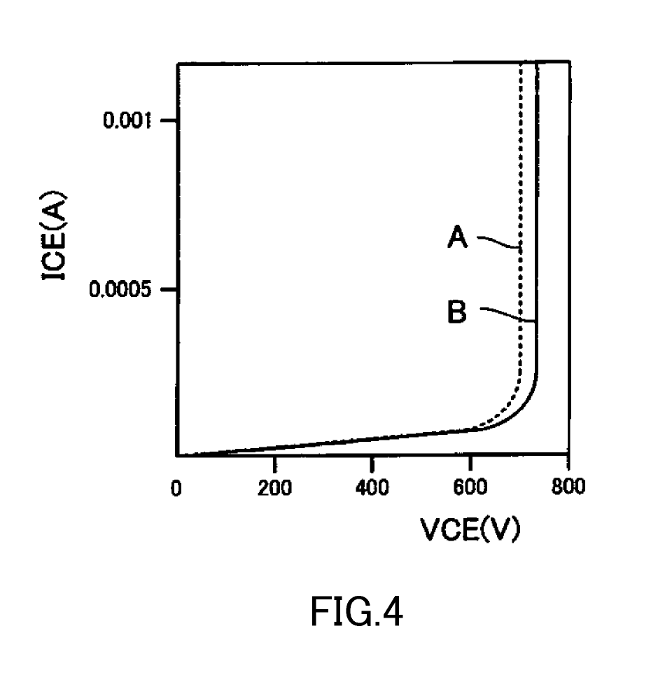

FIG. 4 is a voltage-current characteristic diagram illustrating current ICE (A) of the IGBT device. In detail, FIG. 4 is a characteristic diagram (voltage VCE (V)-current ICE (A) characteristic) illustrating a change of the current ICE (A) when reverse polarity voltage VCE (V) is applied between the emitter electrode 27 and the p+ type collector layer 21 of the IGBT device (illustrated in FIGS. 3A and 3B). A dotted line A represents the VCE-ICE characteristic diagram of the IGBT device with the termination portion illustrated in FIG. 3A. A solid line B represents the VCE-ICE characteristic diagram of the IGBT device with the termination portion illustrated in FIG. 3B. In the voltage VCE(V)-current ICE(A) characteristic illustrated by the dotted line A and the solid line B, the ICE (A) slowly increases with the increase in VCE(V), but the ICE(A) suddenly increases when the VCE (V) exceeds the breakdown voltage of the device.

As can be appreciated from characteristics illustrated in FIG. 4, the IGBT device with the termination portion of the embodiment, which is illustrated in FIG. 3B, has the more improved breakdown voltage than that of the IGBT device with the conventional termination portion illustrated in FIG. 3A. In detail, in the case of the embodiment, the breakdown voltage has 758 V, while in the conventional technology, the breakdown voltage has 740 V.

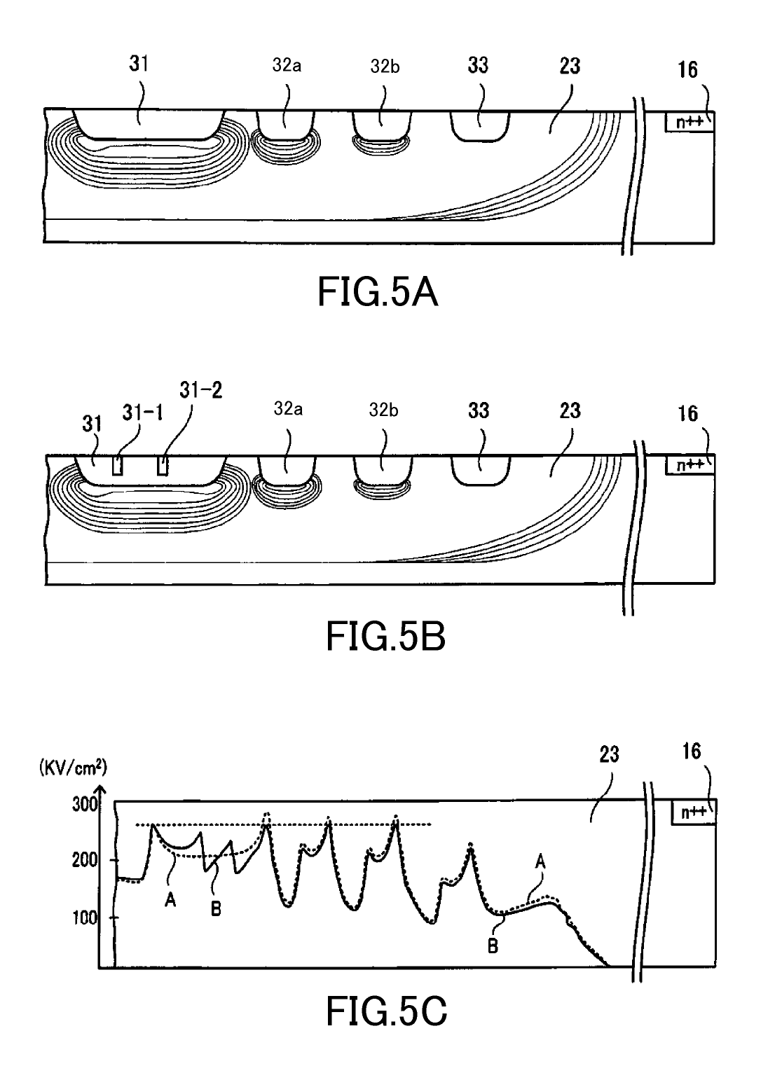

FIG. 5 is an equipotential map inside the IGBT device illustrated in FIG. 3. FIG. 5A is an equi-electric field map in which an electric field distribution inside the device is obtained based on a simulation and the obtained electric field distribution is diagrammed, in the state in which the same reverse polarity VCE voltage (voltage between the emitter electrode 27 and the p+ type collector layer 21) as the breakdown voltage is applied to the IGBT device illustrated in FIG. 3A, that is, just before an avalanche breakdown is occurred. Similarly, FIG. 5B is an equi-electric field map in which the electric field distribution inside the device is obtained based on a simulation just before the avalanche breakdown is occurred, and the obtained electric field distribution is diagrammed. In FIGS. 5A and 5B, only the guard ring 31, the guard ring 32a, the guard ring 32b, and the guard ring 33 of the IGBT device are schematically illustrated and the description of the other structures will be omitted. In FIGS. 5A and 5B, an equi-electric field intensity curve is changed from the upper portion of low potential to the lower portion of high potential.

Comparing FIGS. 5A and 5B, the equi-electric field intensity curve under the bottom surface of the guard ring 31 of FIG. 5A is concentrated at both ends of the guard ring 31, and a peak of electric field is formed at the portions, but the electric field is formed so as to be substantially parallel with the bottom surface of the guard ring 31 at the central portion. On the other hand, the equi-electric field intensity curve under the bottom surface of the guard ring 31 of FIG. 5B is concentrated just under the trenches 31-1, 31-2, in addition to both ends of the guard ring 31 and the peak of the electric field is formed at the portions.

FIG. 5C is a graph illustrating the electric field distributions corresponding to FIGS. 5A and 5B. A vertical axis of FIG. 5C represents an electric field intensity (V/cm²) and a horizontal axis represents a distance (μm) taken along a cross-section of the IGBT device. A dotted line A of FIG. 5C represents the electric field distribution of the IGBT device of a conventional technology illustrated in FIG. 3A. A sold line B of FIG. 5C represents an electric field distribution of the IGBT device according to the embodiment illustrated in FIG. 3B.

As illustrated in the dotted line A and the solid line B, the electric field of the IGBT device (illustrated in FIG. 3B) according to the embodiment is reduced at both ends of the bottom surface of the guard ring 31, as compared with the IGBT (illustrated in FIG. 3A) of a conventional technology. In addition, the peak of electric field occurs just under the two trenches 31-1, 31-2.

Therefore, the IGBT device (illustrated in FIG. 3B) according to the embodiment has the trenches 31-1, 31-2 formed in the guard ring 31, such that the peak of electric field under the guard ring 31 is dispersed at the central portion of the guard ring as well as both ends of the bottom surface of the guard ring. As a result, as illustrated in FIG. 4, it is possible to totally improve the breakdown voltage of the device. In the electric field distribution graph illustrated in FIG. 5C, an area surrounded by a curve representing the electric distribution, a horizontal axis of the graph, and a vertical axis of the graph represents the breakdown voltage. Here, comparing an area surrounded by the dotted line A, a horizontal axis of the graph, and a vertical axis of the graph with an area surrounded by the dotted line B, a horizontal axis of the graph, and a vertical axis of the graph, the area in the case of the solid line B is larger than that of the solid line A.

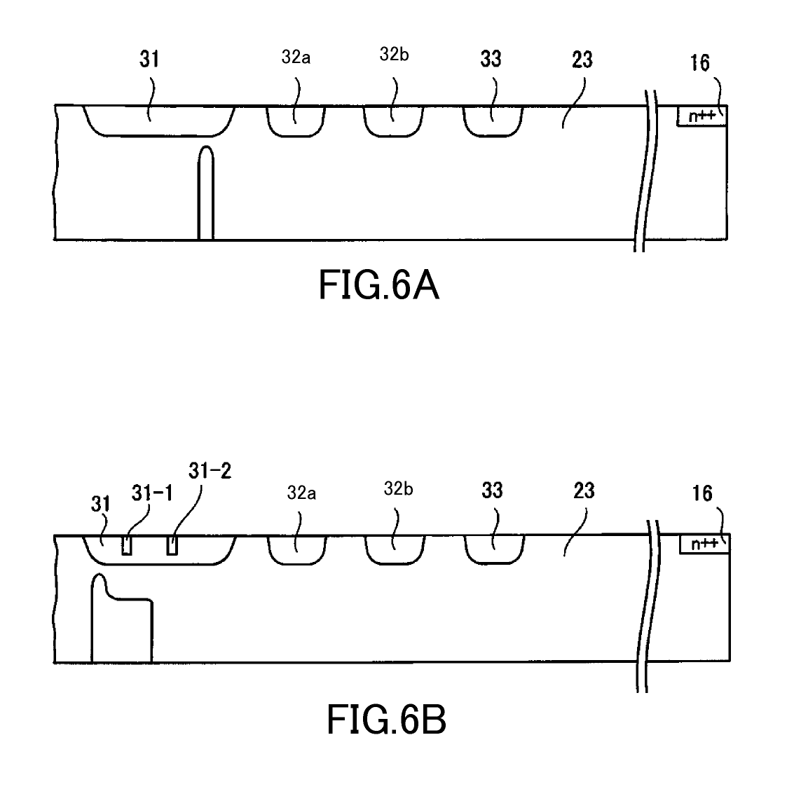

FIG. 6 is a current distribution diagram inside the IGBT device (illustrated in FIG. 3A). FIG. 6A is a current distribution diagram in which a current distribution inside the device is obtained based on a simulation, and the obtained current distribution is diagrammed, in the state in which the same reverse polarity VCE voltage (voltage between the emitter electrode 27 and the p+ type collector layer 21) as the breakdown voltage to the IGBT device (illustrated in FIG. 3A) is applied, that is, just before avalanche breakdown is generated. Similarly, FIG. 6B is a current distribution diagram in which the current distribution inside the device (illustrated in FIG. 3B) is obtained at the time of applying the reverse polarity VCE voltage based on a simulation and the obtained current distribution is diagrammed. Similarly to FIGS. 5A and 5B, FIGS. 6A and 6B schematically illustrate only the guard ring 31, the guard ring 32a, the guard ring 32b, and the guard ring 33 of the IGBT device and the description of the other structures will be omitted.

Comparing FIGS. 6A and 6B, in the conventional technology (illustrated in FIG. 6A), the current ICE between the collector and the emitter is concentrated on the outer circumferential end of the guard ring 31. On the other hand, in the embodiment (illustrated in FIG. 6B), the current ICE is dispersed from the inner circumferential end of the guard ring 31 to the central portion of the guard ring 31. Therefore, in the embodiment, current is not concentrated on one point but is dispersed, and thus the breakage of the device is suppressed. It is possible to improve the breakdown voltage of the device.

From the foregoing simulation results, in the embodiment, by providing the trench buried the insulator 50 in the guard ring, it is possible to increase the potential around the lower portion of the trench, and to disperse the electric field concentration point. Therefore, it is possible to improve the breakdown voltage.

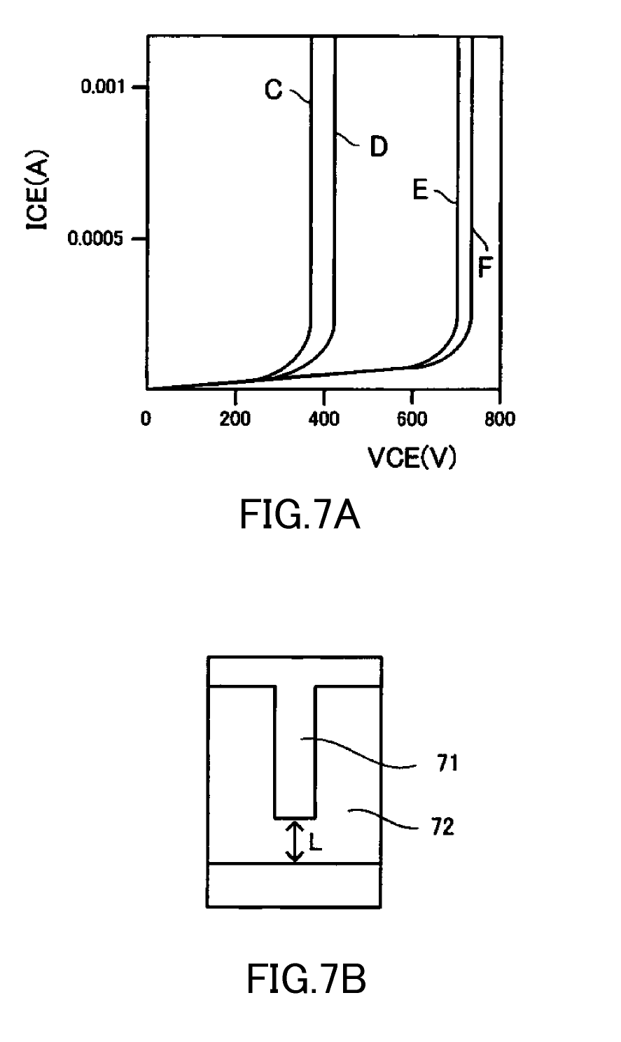

FIG. 7 is a graph illustrating the change of the breakdown voltage of the IGBT device. FIG. 7A is a graph illustrating a result of simulating the change of the breakdown voltage of the IGBT device when an interval L between a bottom surface of a trench 71 and a bottom surface of a guard ring 72 that are illustrated in FIG. 7B is changed. In FIG. 7A, a solid line C represents an interval L of 0 μm, a solid line D represents an interval L of 1 μm, a solid line E represents the guard ring structure without the trench, and a solid line F represents an interval L of 2 μm.

As illustrated in FIG. 7A, when the interval L is 2 μm or more, the breakdown voltage of the IGBT device is increased in comparison with the guard ring structure (solid line E) without the trench, but when the interval L is 2 μm or less, the breakdown voltage of the IGBT device is reduced.

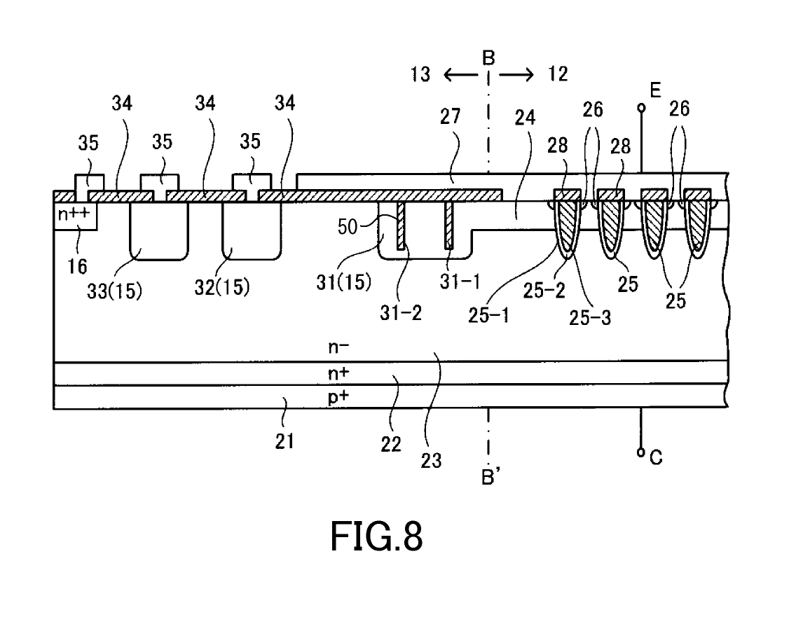

A power semiconductor device according to a second embodiment will be described with reference to the accompanying drawings. FIG. 8 is a partial cross-sectional view illustrating a schematic configuration of an IGBT device. Meanwhile, in FIG. 8, components corresponding to the components of the IGBT device according to the first embodiment illustrated in FIG. 2 are denoted by the same reference numerals and the detailed description will be omitted.

As illustrated in FIG. 8, in the IGBT device of the embodiment, the guard ring 31 includes the trench 31-1 and the trench 31-2, but the guard ring 32 and the guard ring 33 do not include the trench. The other components are the same as those of the first embodiment.

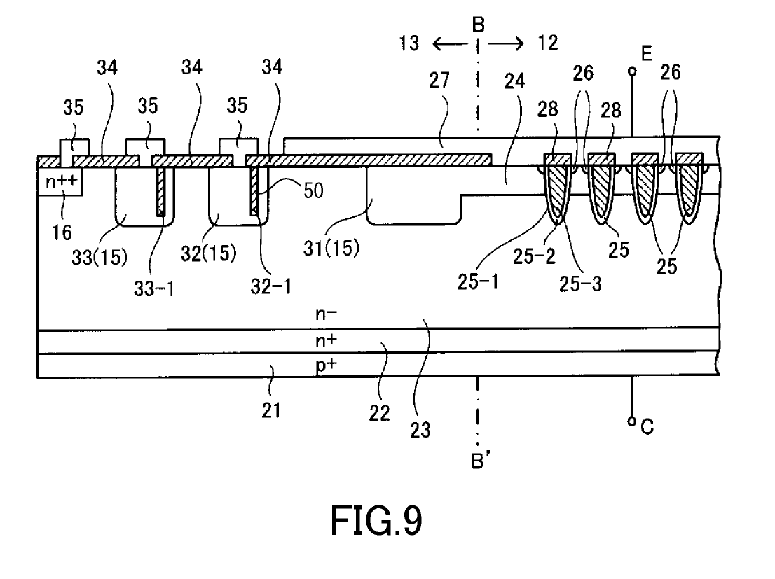

A power semiconductor device according to a third embodiment will be described with reference to the accompanying drawings. FIG. 9 is a partial cross-sectional view illustrating a schematic configuration of an IGBT device. Meanwhile, in FIG. 9, components corresponding to the components of the IGBT device according to the first embodiment illustrated in FIG. 2 are denoted by the same reference numerals and the detailed description will be omitted.

As illustrated in FIG. 9, in the IGBT device according to the embodiment, the guard ring 31 does not include the trench, but the guard ring 32 includes the trench 32-1, the guard ring 33 includes the trench 33-1. The other components are the same as those of the first embodiment.

In the termination of the semiconductor device having the guard ring structure according to the foregoing embodiments, the electric field concentration point is dispersed and the breakdown voltage increases, by forming the trench buried the insulator in the guard ring. For the purpose, it is evident that other combinations can be implemented in addition to the foregoing embodiments.

The foregoing embodiments describe the IGBT device as the power semiconductor device, but the invention is not limited thereto but can also be applied to a power MOSFET as the power semiconductor device or a MOS type semiconductor device including the general power semiconductor device.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device, comprising:
a semiconductor substrate including a drift layer with a first conductive type;
a base layer with a second conductive type, selectively formed in a surface of the drift layer;
a device portion formed on the surfaces of the base layer and the drift layer;
a plurality of guard rings with a second conductive type, selectively formed in the surface of the drift layer around the device portion; and
an insulator buried in at least one of the guard rings.

2. The power semiconductor device according to claim 1, wherein a trench is disposed in the guard ring, and the insulator is buried in the trench.

3. The power semiconductor device according to claim 1, wherein a distance between a bottom of the insulator and a bottom of the guard ring is at least 2 μm or more.

4. The power semiconductor device according to claim 3, wherein the plurality of guard rings includes an innermost circumferential guard ring disposed in the vicinity of the device portion, at least one outer circumferential guard ring disposed at an outside of the innermost circumferential guard ring, and an outermost circumferential guard ring disposed at the outside of the outer circumferential guard ring, and the innermost circumferential guard ring has the insulator disposed in the vicinity of both ends of the guard ring in parallel with a diameter direction.

5. The power semiconductor device according to claim 4, wherein the outer circumferential guard ring and the outermost circumferential guard ring each have the insulators disposed in the vicinity of the inner circumferential ends in parallel with the diameter direction.

6. The power semiconductor device according to claim 3, wherein the plurality of guard rings includes an innermost circumferential guard ring disposed in the vicinity of the device portion, at least one outer circumferential guard ring disposed at an outside of the innermost circumferential guard ring, and an outermost circumferential guard ring disposed at the outside of the outer circumferential guard ring, and the outer circumferential guard ring and the outermost circumferential guard ring each have the insulator disposed in the vicinity of the inner circumferential ends in parallel with a diameter direction.

7. The power semiconductor device according to claim 1, wherein the guard ring is deeper than the base layer.

8. The power semiconductor device according to claim 1, wherein an EQPR layer is disposed at outside of the plurality of guard rings.

9. The power semiconductor device according to claim 8, wherein the EQPR layer, at least one outer circumferential guard ring disposed at the outside of the innermost circumferential guard ring, and the outermost circumferential guard ring disposed at the outside of the outer circumferential guard ring are connected with a floating field electrode.

10. The power semiconductor device according to claim 9, wherein the innermost circumferential guard ring contacts the base layer and is connected to an emitter electrode via the base layer.

11. The power semiconductor device according to claim 2, wherein the insulator is any one of a silicon oxide film, an undoped polycrystalline silicon film, an undoped amorphous silicon film, and an insulating organic film.

12. The power semiconductor device according to claim 11, wherein a thermally-oxidized silicon oxide film is provided at a side and a bottom surface of the trench.

13. The power semiconductor device according to claim 1, wherein the power semiconductor device is a power MOSFET.

14. The power semiconductor device according to claim 1, wherein the power semiconductor device is IGBT further including a buffer layer with a first conductive type and a collector layer with a second conductive type disposed on a surface facing the base layer of the drift layer.
